(19) United States
(12) Patent Application Publication
(10) Pub. No.: US 2007/0019337 A1
(43) Pub. Date: Jan. 25, 2007

(54) Magnetic elements having improved switching characteristics and magnetic memory devices using the magnetic elements

(76) Inventors: Dmytro Apalkov, Milpitas, CA (US); Yiming Huai, Pleasanton, CA (US)

Correspondence Address: SAWYER LAW GROUP LLP, P O BOX 51418, PALO ALTO, CA, 94303, US

(21) Appl. No.: 11/185,507

(22) Filed: Jul. 19, 2005

(51) Int. Cl. G11B 5/127; H01L 21/00; G11B 5/33; G11C 11/15; G11C 11/00

(52) U.S. Cl. 360/324.1; 365/173; 365/158

(57) ABSTRACT

A method and system for providing a magnetic element and a memory using the magnetic element are described. The method and system include providing a pinned layer, providing a spacer layer, and providing a free layer. The spacer layer is nonferromagnetic and resides between the pinned layer and the free layer. At least the free layer has a first end portion, a second end portion and a central portion between the first end portion and the second end portion. The first end portion, the second end portion and the central portion form an S-shape. At least one of the first end portion and the second end portion includes a curve. The magnetic element is also configured to allow the free layer to be switched at least in part due to spin transfer when a write current is passed through the magnetic element.

### FIELD OF THE INVENTION

The present invention relates to magnetic memory systems, and more particularly to a method and system for providing a magnetic element that employs a spin transfer effect in switching, that has improved switching characteristics, and that can be used in a magnetic memory such as magnetic random access memory (“MRAM”).

### BACKGROUND OF THE INVENTION

FIGS. 1A and 1B depict conventional magnetic elements 10 and 10′. The conventional magnetic element 10 is a spin valve and includes a conventional antiferromagnetic (AFM) layer 12, a conventional pinned layer 14, a conventional nonmagnetic spacer layer 16 and a conventional free layer 18. Other layers (not shown), such as seed or capping layer may also be used. The conventional pinned layer 14 and the conventional free layer 18 are ferromagnetic. Thus, the conventional free layer 18 is depicted as having a changeable magnetization 19. The conventional nonmagnetic spacer layer 16 is conductive. The AFM layer 12 is used to fix, or pin, the magnetization of the pinned layer 14 in a particular direction. The magnetization of the free layer 18 is free to rotate, typically in response to an external magnetic field.

The conventional magnetic element 10′ depicted in FIG. 1B is a spin tunneling junction. Portions of the conventional spin tunneling junction 10′ are analogous to the conventional spin valve 10. Thus, the conventional magnetic element 10′ includes an AFM layer 12′, a conventional pinned layer 14′, a conventional insulating barrier layer 16′ and a conventional free layer 18′ having a changeable magnetization 19′. The conventional barrier layer 16′ is thin enough for electrons to tunnel through in a conventional spin tunneling junction 10′.

The conventional magnetic elements 10/10′ typically have an elliptical cross-section. Consequently, the shape 11 and 11′ of the conventional magnetic elements 10 and 10′ is typically an ellipse. Thus, the conventional magnetic elements 10/10′ have a shape anisotropy that provides an easy axis along the long axis (1) of the conventional magnetic elements 10/10′. The magnetization of the pinned layer 14/14′ is typically pinned along this axis. As a result of the shape anisotropy, the stable states of the magnetization 19/19′ of the free layer 18/18′ are parallel or antiparallel to that of the pinned layer 14/14′.

In addition, the aspect ratio and size of the elliptical shape 11/11′ of the conventional magnetic element 10/10′ are selected to maintain the desired thermal stability of the device and improve switching characteristics. Thermal stability is determined by a thermal factor

$$Δ = {K}_{u} V / {k}_{B} T ,$$

where Kᵤ is the uniaxial anisotropy energy density, which has contributions from the intrinsic anisotropy and shape anisotropy, V is the free layer volume, k_{B} is Boltzmann constant, T is the temperature of the free layer 18/18′. For data retention over a ten year interval the thermal factor should be greater than or equal to sixty. For a thermal factor of sixty, the aspect ratio of the ellipse 11/11′is determined based on the volume of the free layer 18/18′. Elliptical shape provides better switching performance, for example faster switching and smaller switching current densities, than the rectangular shape.

Depending upon the orientations of the magnetization 19/19′ of the conventional free layer 18/18′ and the conventional pinned layer 14/14′, respectively, the resistance of the conventional magnetic element 10/10′, respectively, changes. When the magnetization 19/19′ of the conventional free layer 18/18′ is parallel to the magnetization of the conventional pinned layer 14/14′, the resistance of the conventional magnetic element 10/10′ is low. When the magnetization 19/19′ of the conventional free layer 18/18′ is antiparallel to the magnetization of the conventional pinned layer 14/14′, the resistance of the conventional magnetic element 10/10′ is high. Given the elliptical shape 11/11′ of the conventional magnetic elements 10/10′, the stable states for the conventional magnetic elements 10/10′ are a low resistance state and a high resistance state.

To sense the resistance of the conventional magnetic element 10/10′, current is driven through the conventional magnetic element 10/10′. Typically in memory applications, current is driven in a CPP (current perpendicular to the plane) configuration, perpendicular to the layers of conventional magnetic element 10/10′ (up or down, in the z-direction as seen in FIG. 1A or 1B).

In order to overcome certain issues associated with magnetic memories having a higher density of memory cells, spin transfer may be utilized to switch the magnetizations 19/19′ of the conventional free layers 10/10′. Current knowledge of spin transfer is described in detail in the following publications: J. C. Slonczewski, “Current-driven Excitation of Magnetic Multilayers,” Journal of Magnetism and Magnetic Materials, vol. 159, p. L1 (1996); L. Berger, “Emission of Spin Waves by a Magnetic Multilayer Traversed by a Current,” Phys. Rev. B, vol. 54, p. 9353 (1996), and F. J. Albert, J. A. Katine and R. A. Buhrman, “Spin-polarized Current Switching of a Co Thin Film Nanomagnet,” Appl. Phys. Lett., vol. 77, No. 23, p. 3809 (2000). Thus, the following description of the spin transfer phenomenon is based upon current knowledge and is not intended to limit the scope of the invention. When a spin-polarized current traverses a magnetic multilayer such as the magnetic elements 10/10′ in a CPP configuration, a portion of the spin angular momentum of electrons incident on a ferromagnetic layer may be transferred to the ferromagnetic layer. In particular, electrons incident on the conventional free layer 18/18′ may transfer a portion of their spin angular momentum to the conventional free layer 18/18′. As a result, a spin-polarized current can switch the magnetization 19/19′ direction of the conventional free layer 18/18′ if the current density is sufficiently high (approximately 10⁷-10⁸ A/cm²) and the lateral dimensions of the spin tunneling junction are small (approximately less than two hundred nanometers). In addition, for spin transfer to be able to switch the magnetization 19/19′ direction of the conventional free layer 18/18′, the conventional free layer 18/18′ should be sufficiently thin, for instance, preferably less than approximately ten nanometers for Co. Thus, the conventional free layer 18/18′ would typically be thinner than the conventional pinned layer 14/14′ for a magnetic element employing spin transfer. Spin transfer based switching of magnetization dominates over other switching mechanisms and becomes observable when the lateral dimensions of the conventional magnetic element 10/10′ are small, in the range of few hundred nanometers. Consequently, spin transfer is suitable for higher density magnetic memories having smaller magnetic elements 10/10′.

The phenomenon of spin transfer can be used in the CPP configuration as an alternative to or in addition to using an external switching field to switch the direction of magnetization of the conventional free layer 18/18′ of the conventional magnetic element 10/10′. Consequently, spin transfer based switching can be used to switch the magnetization 19/19′ of the free layer 18/18′ to be parallel or antiparallel to that of the pinned layer 14/14′.

Although spin transfer can be used for switching the magnetization 19/19′ of the conventional free layer 18/18′, one of ordinary skill in the art will recognize that a high current density is typically required, particularly if switching is desired to be accomplished in the nanosecond regime. This high current density is one challenge in implementing spin-transfer switching as a recording mode for memory devices using the conventional magnetic element 10/10′. One measure of the current density in the device is given by on-axis magnetization instability current density, introduced by J. Z. Sun in “Spin-current interaction with a monodomain magnetic body: A model study,” Phys. Rev. B, 62, 570-578, 2000. For a monodomain small particle under the influence of spin transfer torque the critical current density, J_{c0,} is given by:

$${J}_{c 0} = \frac{2 ⅇα {M}_{S} {t}_{F} ( H + {H}_{K} + 2 π {M}_{S} )}{ℏη}$$

where e is electron charge, α is the Landau-Lifshitz damping constant, M_{S} is the saturation magnetization, t_{F} is the thickness of the free layer, H is the applied field, H_{K} is the effective uniaxial anisotropy of the free layer (including shape and intrinsic anisotropy contributions), h- is the reduced Planck's constant, and η is the spin polarization factor of the incident current. At this critical current density the initial position of the magnetization 19/19′ of the free layer 18/18′ along the easy axis, 1, becomes unstable and the magnetization 19/19′ starts precessing around the easy axis, 1. As the current is increased further, the amplitude of this precession increases until the magnetization 19/19′ is switched into the other stable state along the easy axis. For fast switching of the magnetization 19/19′ in nanosecond regime, the required current is several times greater than the instability current J_{c0}.

The spin transfer switching of a magnetic element 10/10′ having an elliptical shape 11/11′ can be efficiently studied using micromagnetic modeling. For the conventional magnetic element 10/10′ having an elliptical shape 11, the free layer 18/18′ was assumed to have the elliptical shape 11, a thickness of 2.5 nanometers and cross-section of 200 nm×125 nanometers. These dimensions and a saturation magnetization assumed to be M_{S}=900 emu/cc result in the effective uniaxial anisotropy field H_{K}=H_{K}^{shape}+H_{K}^{int}≈120 Oe and thermal factor, Δ, of approximately sixty, which is desirable. The instability and switching current are very sensitive to the value of M_{S}. Because the switching current J_{c0} increases for higher saturation magnetizations, the switching current may be decreased by using lower M_{S} materials. However, a lower Mₛ increases the value of the exchange length:

$${l}_{ex} = \sqrt{\frac{2 A}{{μ}_{0} {M}_{S}^{2}}}$$

where A is the exchange stiffness constant. The exchange length is an important parameter in determining the magnetization pattern during switching. During the modeling, a constant aspect ratio of the ellipse 11 was used to allow the effect of the exchange length to be examined independently rather than combined effect of modified aspect ratio and exchange length.

FIG. 2 depicts the initial magnetization 19″ for a conventional magnetic element having an elliptical shape 11/11′. For fast switching in nanosecond regime the initial condition of the magnetization of the free layer 18/18′ is important. For elliptical shape 11/11′, the average magnetization for the initial state lies along the long (easy) axis of the ellipse as shown on FIG. 2. The initial spin transfer torque is proportional to sin θ, where θ is the angle (initially very small) between the local magnetization vector and the fixed magnetization direction of pinned layer. As a consequence, the spin transfer torque is very small initially. The fixed magnetization direction of the pinned layer 14/14′ is chosen to be along positive x direction (to the right in FIG. 2).

FIG. 3 depicts the Oersted field 60 induced by the current during switching for the conventional magnetic element having an elliptical shape 11/11′. The onset of precession and the initial motion of the magnetization in this case is created by the non-uniform current-induced in-plane Oersted field 60. This field stimulates the magnetization precession at both ends 62 and 66 of the ellipse 11/11′ where the Oersted field is strongest and forms a large angle with the local magnetization. However, the field creates a significantly smaller torque at the central region 64 of the ellipse 11′. In the central region 64 either the field is small closer to the center or the angle between the field and local magnetization is small, near the boundaries of central region 66. As a result, the field drives the onset of precession in the end domains 62 and 66 of the ellipse 11/11′.

FIGS. 4-5 are graphs 70 and 80, respectively, depicting average magnetization along the easy axis (long axis 1) versus time for the conventional magnetic element having the elliptical shape 11/11′ switched using the spin transfer effect. The graphs 70 and 80 are for conventional magnetic elements having a dual structure, such as a dual spin valve. However, the curves for the graphs 70 and 80 should have substantially the same shape for the magnetic elements 10/10′ having a single structure. The graph 70 depicts curves for the elliptical shape 11/11′ with 1ₑₓ=5.4 nm and J=17 MA/cm² (top), J=9 MA/cm² (middle), and J=8 MA/cm² (bottom). The graph 80 depicts curves for the elliptical shape 11/11′ with 1ₑₓ=5.4 nm and J=16 MA/cm² (top), J=14 MA/cm² (middle), and J=12 MA/cm² (bottom). Referring to FIGS. 2-5, the precession described above continues to be amplified by the spin-transfer torque, creating the magnetization states shown by the curves 72, 74, 76, 82, 84, and 86. Moreover, as the amplitude of end domain precession increases, the central region 64 of the ellipse 11/11′ still experiences very little torque and is in a minimum energy state when the magnetization of this region 64 is aligned with the easy axis of the ellipse 11/11′. This energy minimum is created by effective local field, which due to the mirror symmetry of the state of the magnetization is along the easy axis of the ellipse, creating pinning of the central region 64. In order to cause the switching of the magnetization, the induced symmetry of the magnetization distribution is overcome. As a result the average magnetization experiences large amplitude precession shown in the graphs 70 and 80 for two different values of exchange length even becoming negative whereas the central region of the ellipse still has the magnetization pointing in the original direction. This effective pinning of the central region 64 limits the device performance and introduces dependence on the variation in shape, size, and defects due to fabrication process, which affects the symmetry of the magnetization distribution and consequently the time required to break-up the symmetry and cause the switching. The switching time is defined as the time at which average reduced magnetization component along x axis is equal to zero for the last time before it switches to −1. The switching time thus defined is a good approximation to the minimal pulse width required to switch the system as was confirmed by simulations with different pulse widths at fixed amplitude of the current.

Thus, the conventional magnetic element 10/10′ may require a relatively large critical current density to induce spin transfer switching. In addition, the time required to switch the magnetization direction of the free layer 18/18′ may be relatively long. Several techniques and material optimization have been performed to decrease this current. However, such techniques have attendant drawbacks.

Accordingly, what is needed is a magnetic memory having improved performance and utilizing a localized phenomenon for writing, such as spin transfer, and which has improved switching characteristics. The present invention addresses such a need.

### BRIEF SUMMARY OF THE INVENTION

The present invention provides a method and system for providing a magnetic element and a memory using the magnetic element. The method and system comprise providing a pinned layer, providing a spacer layer, and providing a free layer. The spacer layer is nonferromagnetic and resides between the pinned layer and the free layer. At least the free layer has a first end portion, a second end portion and a central portion between the first end portion and the second end portion. The first end portion, the second end portion and the central portion form an S-shape. At least one of the first end portion and the second end portion includes a curve. The magnetic element is configured to allow the free layer to be switched at least in part due to spin transfer when a write current is passed through the magnetic element.

According to the method and system disclosed herein, the present invention provides a mechanism for programming and reading a magnetic memory including magnetic elements that are programmable by a write current driven through the magnetic elements, for example through the phenomenon of spin transfer.

### BRIEF DESCRIPTION OF SEVERAL VIEWS OF THE DRAWINGS

FIG. 1A is a diagram of a conventional magnetic element.

FIG. 1B is a diagram of another conventional magnetic element.

FIG. 2 is a diagram depicting the initial magnetization for a conventional magnetic element having the shape of an ellipse.

FIG. 3 is a diagram depicting the Oersted field during switching for a conventional magnetic element having the shape of an ellipse.

FIGS. 4-5 are graphs depicting magnetization versus time for a conventional magnetic element switched using spin transfer.

FIG. 6 is a diagram of one embodiment of a magnetic element in accordance with the present invention.

FIG. 7 is a diagram of one embodiment of the S-shape for magnetic element in accordance with the present invention.

FIG. 8 is a diagram depicting the initial magnetization for a magnetic element in accordance with the present invention.

FIG. 9 is a diagram depicting the Oersted field distribution for one embodiment of a magnetic element in accordance with the present invention.

FIGS. 10-11 are graphs depicting magnetization versus time for one embodiment of a magnetic element in accordance with the present invention.

FIGS. 12A-12D depict the magnetization during switching for one embodiment of a magnetic element in accordance with the present invention.

FIG. 13 is a graph depicting switching time versus current density for magnetic elements switched using spin transfer for a first exchange length.

FIG. 14 is a graph depicting switching time versus current density for magnetic elements switched using spin transfer for a second exchange length

FIG. 15 depicts another embodiment of a magnetic element in accordance with the present invention.

FIG. 16 is a flow chart depicting on embodiment of a method in accordance with the present invention for providing a magnetic element in accordance with the present invention.

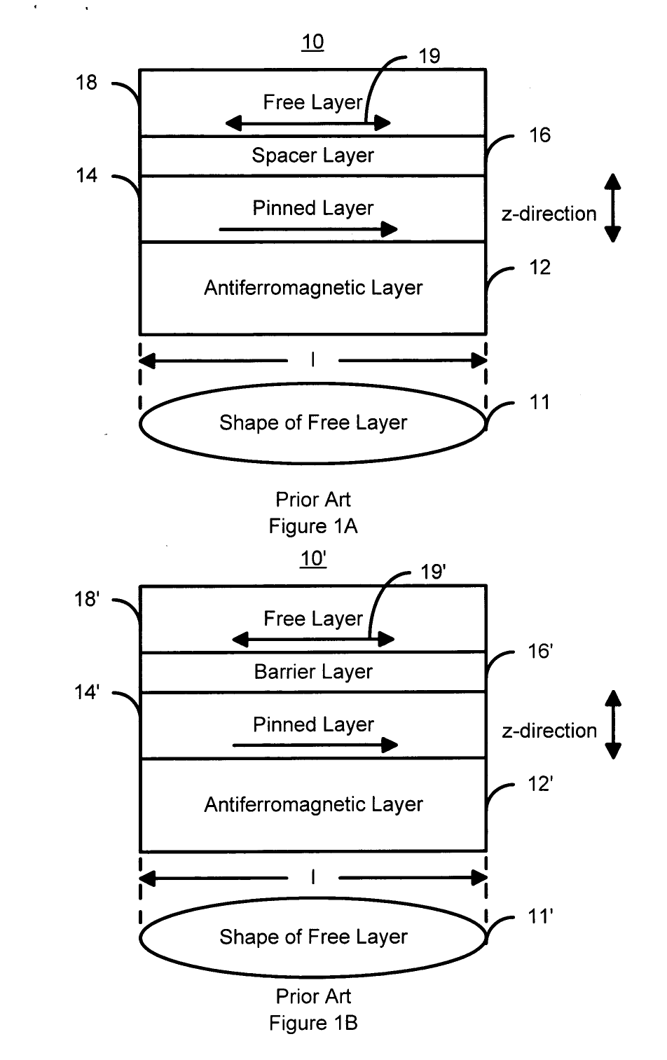

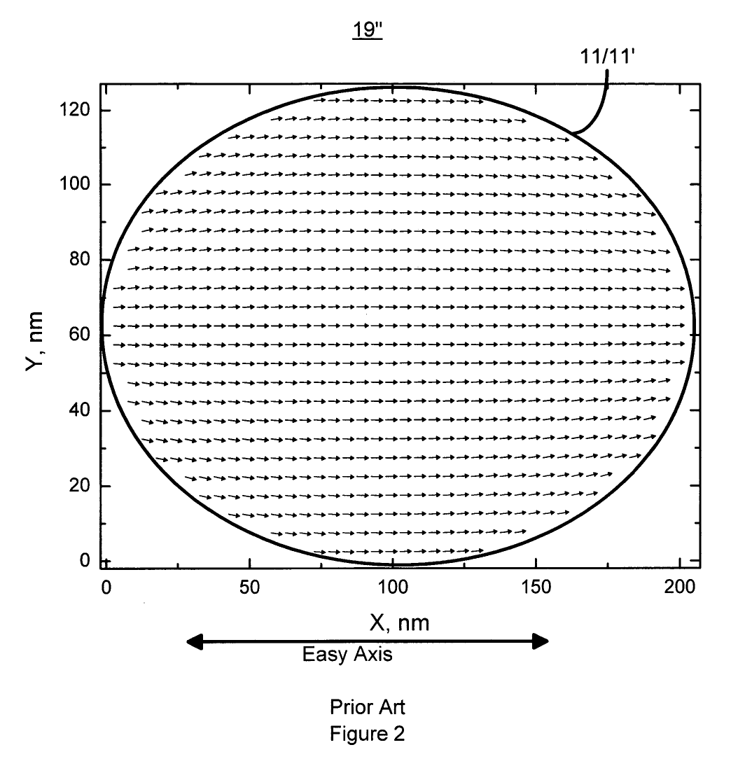

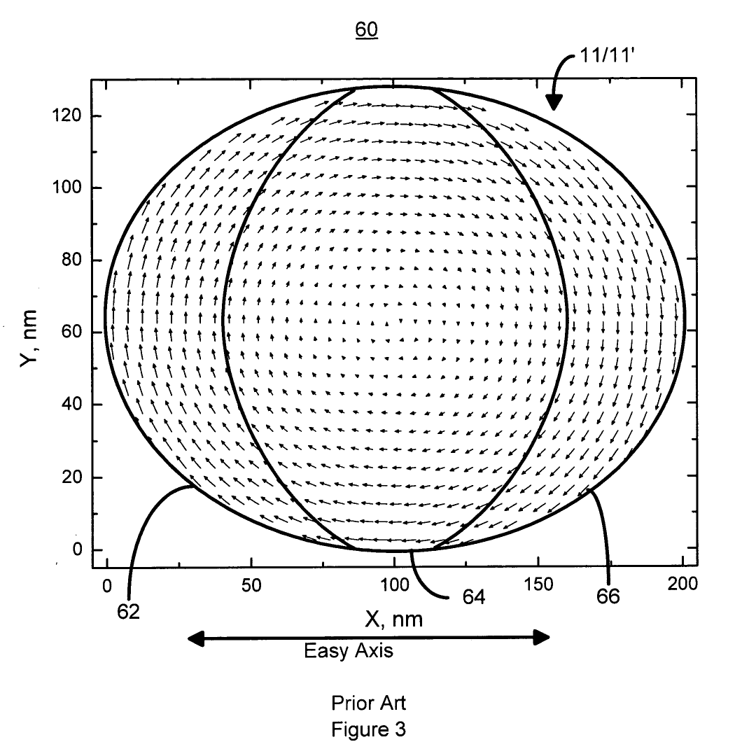

### DETAILED DESCRIPTION OF THE INVENTION

The present invention relates to a magnetic memory. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

The present invention provides a method and system for providing a magnetic element and a memory using the magnetic element. The method and system comprise providing a pinned layer, providing a spacer layer, and providing a free layer. The spacer layer is nonferromagnetic and resides between the pinned layer and the free layer. At least the free layer has a first end portion, a second end portion and a central portion between the first end portion and the second end portion. The first end portion, the second end portion and the central portion form an S-shape. At least one of the first end portion and the second end portion includes a curve. The magnetic element is configured to allow the free layer to be switched at least in part due to spin transfer when a write current is passed through the magnetic element.

The present invention is described in the context of particular magnetic memories having certain components. One of ordinary skill in the art will readily recognize that the present invention is consistent with the use of magnetic memories having other and/or additional components. The present invention will also be described in terms of a particular magnetic element having certain components. However, one of ordinary skill in the art will readily recognize that this method and system will operate effectively for other magnetic memory elements having different and/or additional components and/or other magnetic memories having different and/or other features not inconsistent with the present invention. The present invention is also described in the context of current understanding of the spin transfer phenomenon. Consequently, one of ordinary skill in the art will readily recognize that theoretical explanations of the behavior of the method and system are made based upon this current understanding of spin transfer. One of ordinary skill in the art will also readily recognize that the method and system are described in the context of a structure having a particular relationship to the substrate. However, one of ordinary skill in the art will readily recognize that the method and system are consistent with other structures. In addition, the method and system are described in the context of certain layers being synthetic and/or simple. However, one of ordinary skill in the art will readily recognize that the layers could have another structure. Furthermore, the present invention is described in the context of magnetic elements having particular layers. However, one of ordinary skill in the art will readily recognize that magnetic elements having additional and/or different layers not inconsistent with the present invention could also be used. Moreover, certain components are described as being ferromagnetic. However, as used herein, the term ferromagnetic could include ferrimagnetic or like structures. Thus, as used herein, the term “ferromagnetic” includes, but is not limited to ferromagnets and ferrimagnets. The present invention is also described in the context of single elements. However, one of ordinary skill in the art will readily recognize that the present invention is consistent with the use of magnetic memories having multiple elements, bit lines, and word lines.

The present invention is also described in the context of current understanding of the spin transfer phenomenon. Consequently, one of ordinary skill in the art will readily recognize that theoretical explanations of the behavior of the method and system are made based upon this current understanding of spin transfer. One of ordinary skill in the art will also readily recognize that the method and system are described in the context of a structure having a particular relationship to the substrate. For example, as depicted in the drawings, the bottoms of the structures are typically closer to an underlying substrate than the tops of the structures. However, one of ordinary skill in the art will readily recognize that the method and system are consistent with other structures having different relationships to the substrate. In addition, the method and system are described in the context of certain layers being synthetic and/or simple. However, one of ordinary skill in the art will readily recognize that the layers could have another structure. Furthermore, the present invention is described in the context of magnetic elements having particular layers. However, one of ordinary skill in the art will readily recognize that magnetic elements having additional and/or different layers not inconsistent with the present invention could also be used. Moreover, certain components are described as being ferromagnetic. However, as used herein, the term ferromagnetic could include ferrimagnetic or like structures. Thus, as used herein, the term “ferromagnetic” includes, but is not limited to ferromagnets and ferrimagnets.

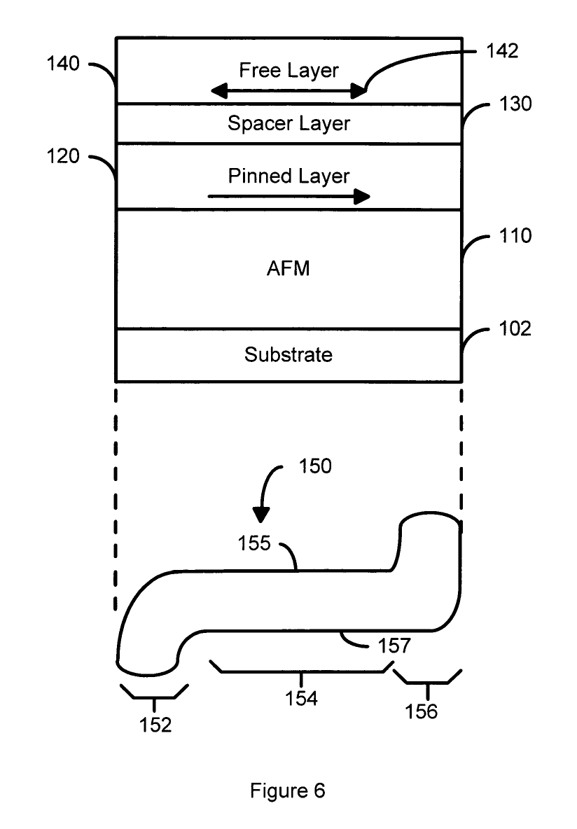

FIG. 6 is a diagram of one embodiment of a magnetic element 100 in accordance with the present invention. The magnetic element 100 includes ferromagnetic layers 120 and 140, which are separated by a spacer layer 130 and is formed on a substrate 102. Although not depicted, the magnetic element 100 may utilize seed layers (not shown) and a capping layer (not shown). The ferromagnetic layers 120 and 140 are preferably a pinned layer and free layer, respectively. For example, the layers 120 and 140 may be simple ferromagnetic layers or may be synthetic layers including two or more ferromagnetic layers separated by a nonmagnetic conductive spacer layer. The spacer layer 130 may be a conductive layer, for example including Cu, or may be an insulating, tunneling barrier layer. The magnetization of the pinned layer 120 is preferably pinned by the pinning layer 110. The pinning layer 110 is preferably an antiferromagnetic (AFM) layer, which pins the magnetization of the pinned layer 110 via an exchange coupling. The magnetic element 100 is configured so that the magnetization 142 of the free layer 140 can be switched via spin transfer when a sufficient write current is driven through the magnetic element 100. Consequently, the lateral dimension, 1, of the magnetic element 100 is small, in the range of few hundred nanometers. In addition, although the free layer 140 is depicted as being formed above the pinned layer 120 in relation to the substrate, nothing prevents a different order of layers. At least the free layer 140 has a cross section shape 150 that is substantially S-shaped. In a preferred embodiment, the entire magnetic element 100, substantially shares the S-shape 150. In an alternate embodiment, layers in addition to the free layer 140 can have the S-shape 150 without requiring that the entire magnetic element 100 has the S-shape 150. The S-shape 150 can be considered to be made up of end portions 152 and 156 separated by a center portion 154. At least one of the end portions 152 and 156 includes a curve. In a preferred embodiment, the ends of the end portions 152 and 156 as well as where the end portions 152 and 156 join the center portion 154 are curved. Also in a preferred embodiment, the center portion 154 and end portions 152 and 156 are configured so that there are no sharp corners on the S-shape 150. The end portions 152 and 156 preferably have the same dimensions. However, in an alternate embodiment, the end portions 152 and 156 may have different dimensions. The edges 155 and 157 of the center portion are preferably straight. Although in a preferred embodiment, the edges 155 and 157 are parallel, in another embodiment the edges 155 and 157 may not be parallel. As discussed below, the S-shape 150 may aid in improving the switching characteristics of the magnetic element 100. In particular, the S-shape 150 may allow for faster switching of the magnetization 142 of the free layer 140.

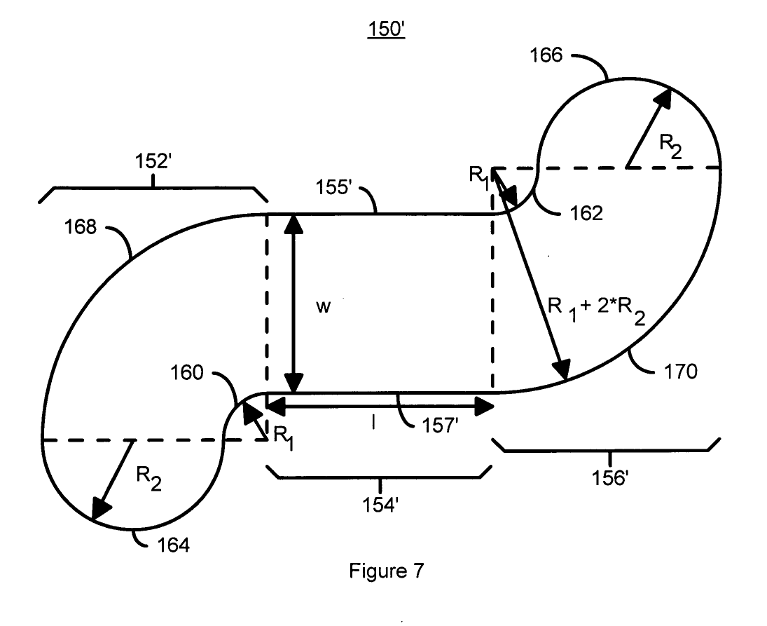

FIG. 7 is a diagram of a preferred embodiment of the S-shape 150′ for at least the free layer 140 and preferably the entire magnetic element 100 in accordance with the present invention. The S-shape 150′ is analogous to the S-shape 150 depicted in FIG. 6. Consequently, the S-shape 150′ includes end portions 152′ and 156′ separated by a central portion 154′. The S-shape 150′ is substantially free of corners or other sharp transitions. In addition, each of the end portions 152′ and 156′, not only have curved transition adjacent to the center portion 154′, but also have rounded ends. In a preferred embodiment, the end portions 152′ and 156′ have inside curves 160 and 162, respectively, outside curves 168 and 170, respectively, and end curves 164 and 166. In a preferred embodiment, the curves 160 and 162 are the same size and shape. Similarly, the curves 164 and 166 preferably have the same size and shape. Thus, the inside curves 160 and 162 are arcs, preferably ninety degrees, of a circle having radius R₁. The ends of the regions 164 and 166 are preferably semicircles having a radius R₂. The outside curves 168 and 170 are preferably an arc, for example ninety degrees, of a circle having a radius equal to R₁+2R₂. The edges 155′ and 157′ of the central portions are preferably parallel. Consequently, the width, w, of the central portion 154′ is preferably the same as 2R₂. With these dimensions, the S-shape 150′ is substantially free of corners or other sharp transitions. In a preferred embodiment, the radii R1 and R2 are less than or equal to two hundred nanometers. Also in a preferred embodiment, the width, w, is on the order of four hundred nanometers or less. However, in an alternate embodiment, larger dimensions are possible.

The magnetic element 100 in which at least the free layer 140 has the S-shape 150 or 150′ has improved switching characteristics. Because of the S-shape 150 or 150′, the magnetic element 100 may exhibit faster switching at a lower switching current, switching which is less sensitive to shape variations that may occur during fabrication, and may provide more reproducible switching for an array of magnetic elements using the S-shape 150 or 150′ in an array. Moreover, because the S-shapes 150 and 150′ may have a reduced number of sharp edges, and preferably has no sharp edges, switching is improved and irregularities in shape due to fabrication problems of making sharp edges are reduced. Moreover, although the shapes 150 and 150′ were described in the context of the magnetic element 100 having specific layers, the shapes 150 and 150′ may be used with magnetic elements having different and/or additional layers.

The improved switching characteristics of magnetic elements, such as the magnetic element 100, using the shape 150 and/or 150′ may be illustrated by micromagnetic simulations. A series of micromagnetic simulations based on Landau-Lifshitz equation with the effect of spin transfer torque included by Slonczewski model were performed. These results for the S-shape 150 can be compared to the results, described above, for a conventional magnetic element having the shape 11 or 11′. The use of micromagnetic modeling, a particular explanation of the switching, and/or parameters used in modeling are for explanatory purposes only and are not intended to limit the scope or applicability of the present invention.

For micromagnetic modeling, the size of the S-shape is determined by the four parameters: 1, w, R₁, and R₂ for the S-shape 150′. These parameters are chosen so that the area of the S-shape 150 and 150′ is equal to that of the ellipse 11/11′ described above. Consequently, for the purposes of the micromagnetic simulations, 1=140 nm, w=70 nm, R₁=0, R₂=w/2=35 nm. One important parameter that determines the magnetization pattern during switching is the exchange length, described above. As mentioned previously, the exchange length is given by:

$${l}_{ex} = \sqrt{\frac{2 A}{{μ}_{0} {M}_{S}^{2}}}$$

where A is the exchange stiffness constant. In the simulations, two different values of exchange length lₑₓ=4.4 nm (A=1×10⁻¹¹ J/m, M_{S}=900 emu/cc) and lₑₓ=5.4 nm (A =1.5×10⁻¹¹ J/m, M_{S}=900 emu/cc or A=1×l0⁻¹¹ J/m, M_{S}=750 emu/cc) were used and the results compared. The instability and switching current are very sensitive to the value of M_{S}. Because the switching current J_{c0} depends upon the magnetization, the switching current may be decreased by using lower Ms materials. However, as can be seen by the equation for the exchange length, a lower Ms increases the value of exchange length. However, as discussed above, the simulations use a higher value of exchange stiffness to keep the aspect ratio of the ellipse 11/11′ constant for comparison. The constant aspect ratio of the ellipse 11/11′ allows the effect of the exchange length to be examined independently rather than combined effect of modified aspect ratio and exchange length.

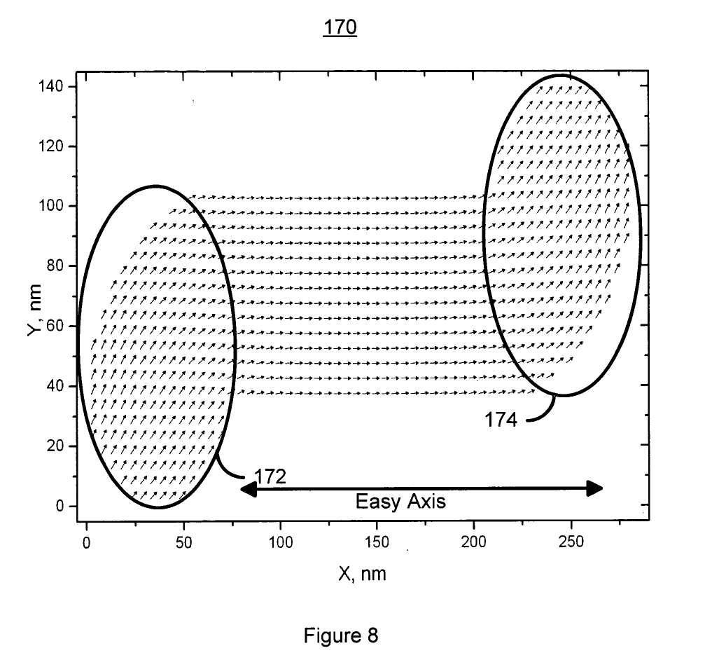

FIG. 8 is a diagram depicting the initial magnetization 170 for a magnetic element in accordance with the present invention in which at least the free layer has the shape 150′. The initial magnetization configuration 170 has end domains 172 and 174 with magnetization vectors at angles with respect to the easy axis. The presence of the domains 172 and 174 results in non-zero initial spin transfer torque as the current pulse is passed through the device 100′.

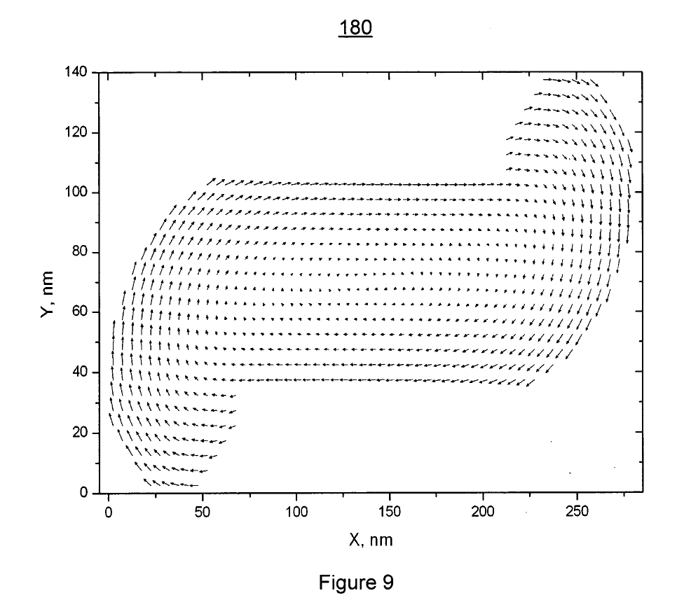

The current in the magnetic element 100 with cross-section in the S-shape 150′ also results in a different Oersted field distribution. FIG. 9 depicts the Oersted field distribution 180 in the S-shape 150′. Referring to FIGS. 8-9, the use of the S-shape 150′, and the presence of the domains 172 and 174 breaks the symmetry of switching because the Oersted field 180 is primarily in the same direction as the magnetization for the domain 172, but in the opposite direction of magnetization for the domain 174. The situation is reversed as the direction of the current is reversed. Consequently, switching is improved.

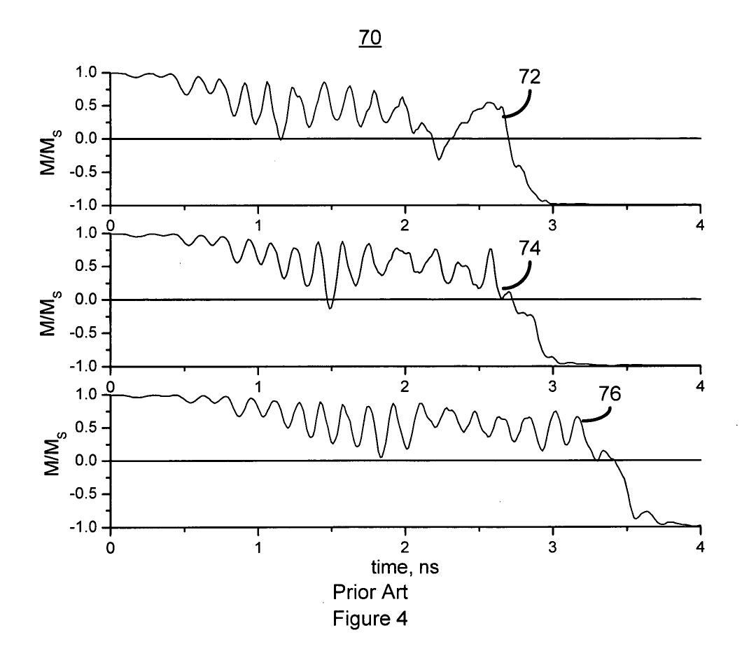

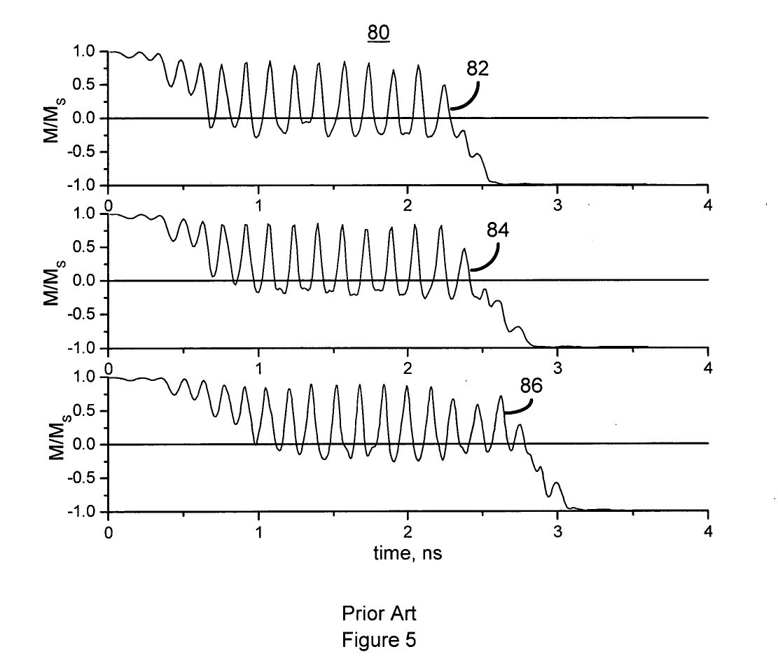

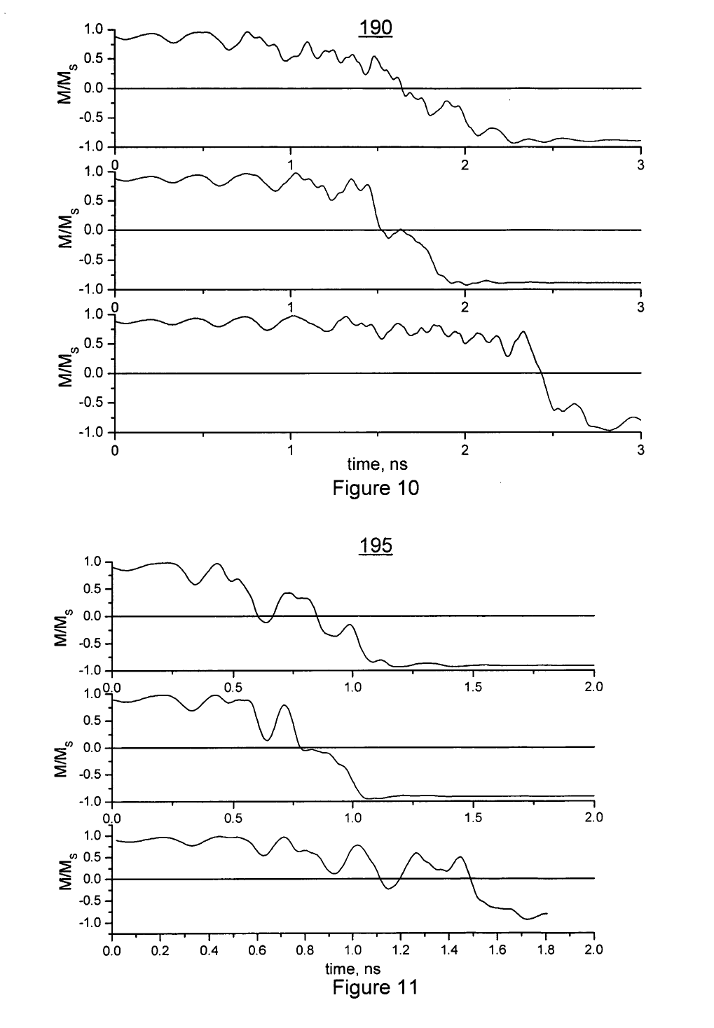

The improvement in switching can be seen in FIGS. 10-11, which are graphs 190 and 195, respectively, depicting average magnetization projection onto the long axis versus time for one embodiment of a magnetic element in accordance with the present invention in which at least the free layer has the S-shape 150′. The magnetic element for which the graphs 190 and 195 were produced is a dual structure, such as the structure discussed below. However, the results would be analogous to a structure such as that of the magnetic element 100. It is expected that the general shape of the curves in the graphs 190 and 195 would be the same, but that the current would be increased roughly by a factor of two. FIG. 10 depicts curves for the S-shape 150′ where 1ₑₓ=4.4 nm and J=11 MA/cm² (top), J=9 MA/cm² (middle), and J=8 MA/cm² (bottom). FIG. 11 depicts curves for the S-shape 150′ where 1ₑₓ=5.4 nm and J=11 MA/cm₂ (top), J=9 MA/cm² (middle) and J=8 MA/cm² (bottom). As can be seen from comparing the graphs 190 and 195 to the graphs 70 and 80 of FIGS. 4-5, for analogous magnetic parameters the switching of the magnetic element 100 having the shape 150′ is more efficient and, therefore, faster than the switching of the conventional magnetic element 10/10′ having the elliptical shape 11/11′.

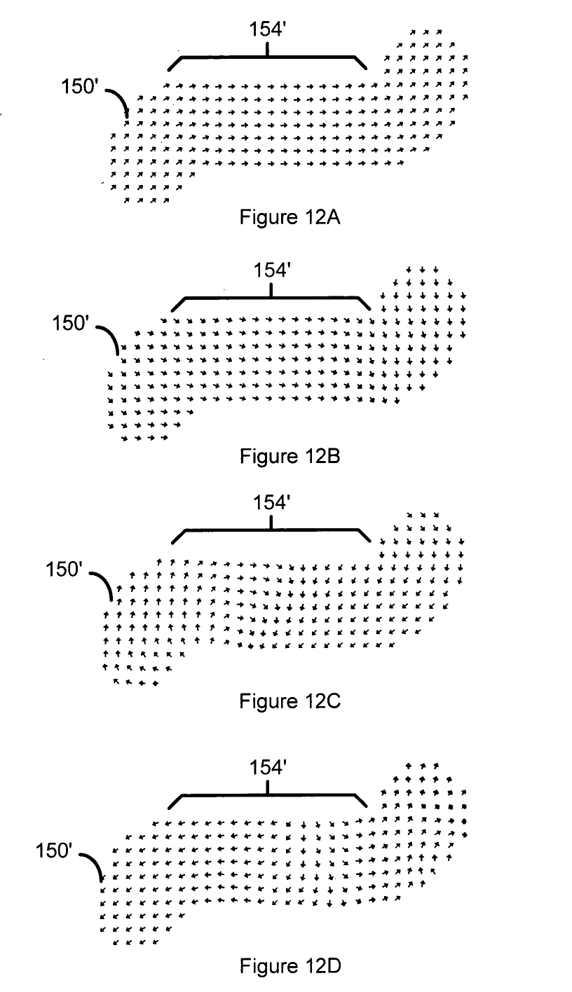

FIGS. 12A-12D depicts the magnetization distribution of a magnetic element in which at least the free layer has the S-shape 150′ at various times during spin transfer driven switching. In contrast to the conventional elliptical shape 11/11′, the central region 154′ of the S-shape 150′ does not have effective magnetization pinning. In addition, symmetric magnetization patterns may be eliminated during the switching. The switching time for S-shape 150′ may be greatly reduced. For example, for the S-shape 150′ depicted in FIG. 12, for exchange length lex=4.4 nm and J=8 MA/cm² the switching time may be reduced from 3.41 ns for the elliptical shape 11/11′ to 2.43 ns for S-shape 150′. Similarly, for 1ₑₓ₌5.4 nm and J=14 MA/cm² the switching time may be reduced from 2.42 ns to 0.78 ns. The higher reduction in switching current for greater exchange length may be due to the higher stability of central region 66 of the elliptical shape 11/11′ as well as a more uniform initial magnetization. These data can be viewed as indicating a switching current reduction at a fixed pulse width. For example, for a pulse width of two nanoseconds, S-shape 150′ requires the application of current J≈8.5 MA/cm² whereas the switching current for elliptical shape is J≈11.0 MA/cm². This represents approximately a twenty-three percent reduction of the switching current reduction. For higher exchange length the corresponding switching currents may be J≈9.5 MA/cm² for the S-shape 150′ and J≈18 MA/cm² for the elliptical shape 11/11′. This may result in a reduction in the switching current of approximately forty-seven percent.

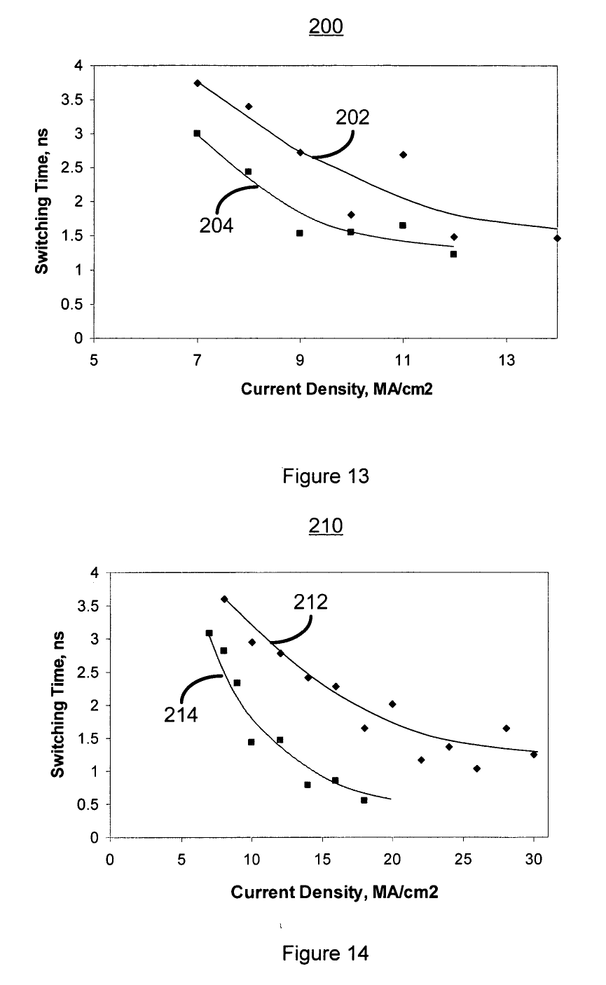

The expected improvement in switching characteristics may also be seen in FIGS. 13-14, which depict graphs 200 and 210, respectively, of switching time versus current density for two values of the exchange length. The curves 202 and 212 are for conventional magnetic elements having an elliptical shape 11/11′. The curves 204 and 214 are for magnetic elements in accordance with the present invention in which at least the free layer has the shape 150′. The curves 204 and 214 are consistently lower than the curves 202 and 212, respectively. Thus, over a range of current densities, the magnetic elements using the S-shape 150/150′ may exhibit a reduced switching time and improved switching characteristics.

In addition to the advantages described above, a magnetic element having the S-shape 150 or 150′ may use a shorter length current pulse when being written (e.g. switched). For the elliptical shape 11/11′ of the conventional magnetic element 10/10′, there are irregularities in switching time depending upon the applied current density. As shown in FIG. 13, for some currents, such as eleven mega amps per centimeter squared require, very long switching times and, therefore, very long pulse widths may be required for the conventional elliptical shape 11/11′. The origin of this phenomenon is believed to be related to the stability of end domain magnetization precession with magnetization of the central region pinned in the initial direction. This behavior is not desirable for the device because there is expected to be a distribution of the magnetic element shape and size over the cell array. Consequently, some elliptical magnetic elements 11/11′ in the array may require longer pulse widths. In contrast, as can be seen from curves 204 and 214, the distribution of the switching times for the S-shape 150/150′ indicate a smoother dependence of switching time on applied current. Consequently, magnetic elements using the S-shape 150/150′ may have more uniform switching characteristics.

Furthermore, the S-shape 150/150′ may have fewer initial stable magnetization states than a magnetic element using the elliptical shape 11/11′. The ellipse 11/11′ has two different stable magnetization states (termed the C-state and S-state), that can affect the switching current for conventional magnetic elements 10/10′. Because of variations in fabrication, for instance, different conventional magnetic elements 10/10′ may have widely varied switching characteristics. However, S-shape 150/150′ has a strong configurational anisotropy. Consequently, the magnetization should be in the S-state even if the small variations in the shape are present due to fabrication process. The switching characteristics of the magnetic element 100 may be more uniform, thereby decreasing the number of false bits.

Thermal stability for both the S-shape 150/150′ and the ellipse 11/11′ can be roughly estimated from easy-axis hysteresis loop calculation. The S-shape 150/150′ exhibits a higher zero temperature coercivity H_{C}≡H_{K}≈250 Oe than the elliptical shape 11/11′, which has H_{C}≡H_{K}≈120 Oe. As a result, magnetic elements using the S-shape 150/150′ may have a higher thermal stability factor and, therefore, a longer data retention time.

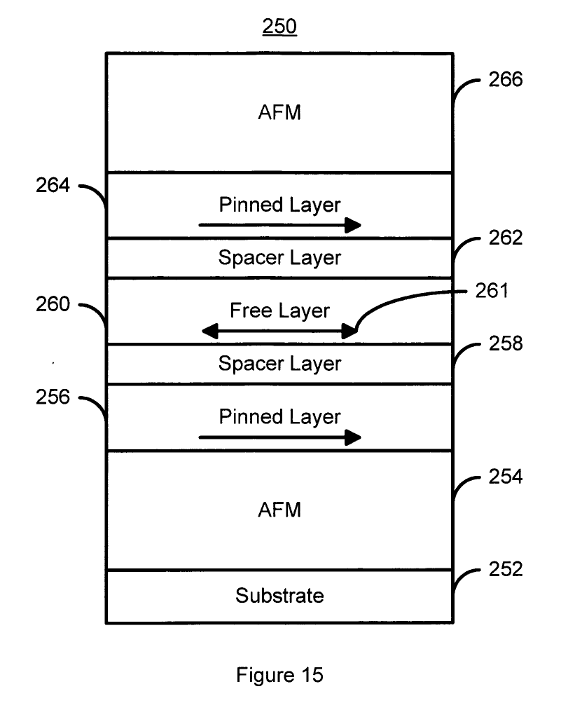

FIG. 15 depicts another embodiment of a magnetic element 250 in accordance with the present invention. Although not depicted in FIG. 15, the magnetic element 250 has the shape 150 or 150′. The magnetic element 250 is provided on a substrate 254. The magnetic element 250 includes at least pinned layers 256 and 264, spacer layers 258 and 262, and at least one free layer 260 having a magnetization 261. The pinned layers 256 and 264 are analogous to the pinned layer 120. Thus, the pinned layers 256 and 264 may be simple or synthetic and preferably have their magnetizations pinned by pinning layers 254 and 266, respectively. The pinning layers 254 and 266 are preferably AFM layers. Although not depicted, the magnetic element 250 may utilize seed layers (not shown) and/or capping layer(s).

The free layer 260 is analogous to the free layer 140. The free layer 260 may thus be simple or synthetic. In addition, the free layer 260 is the data storage layer. Similarly, the spacer layers 258 and 262 are analogous to the spacer layer 130. Consequently, one or both of the spacer layers 258 and 262 may be an insulating tunneling barrier layer. One or both of the spacer layers 258 and 262 may be conductive. In one embodiment, one of the spacer layers 258 and 262 is insulating while the other is conducting.

Because the magnetic element 250 has the S-shape 150 or 150′, the magnetic element 250 shares the benefits of the magnetic element 100. Thus, the magnetic element 250 may have improved switching characteristics including a shorter switching time for a given current density, smaller switching current for a given pulse width, as well as improved thermal stability and uniformity of switching.

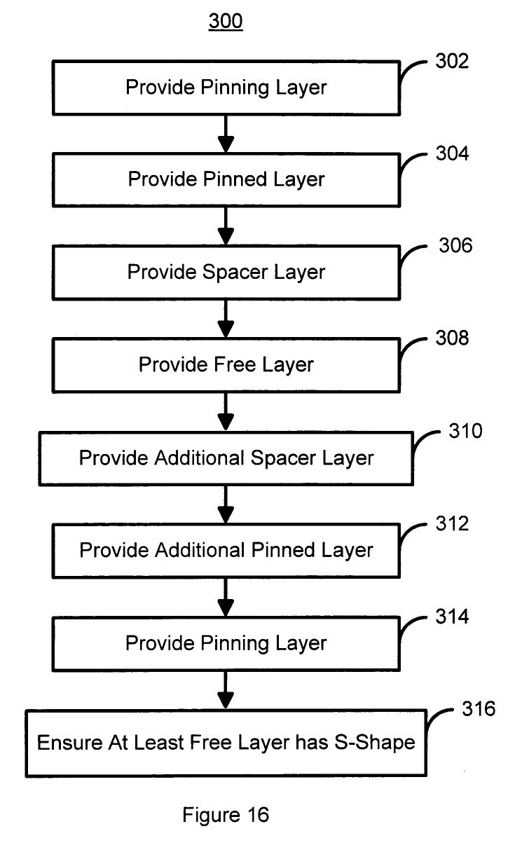

FIG. 16 is a flow chart depicting on embodiment of a method 300 in accordance with the present invention for providing a magnetic element in accordance with the present invention. The method 300 is described in the context of the magnetic elements 100 and 250. However, nothing prevents the method 300 from being used with other magnetic elements having different and/or additional layers. Furthermore, for simplicity, some steps may be omitted.

The method 300 includes providing a pinning layer 110 or 254, via step 302. The pinned layer 120 or 256 as well as the spacer layer 130 or 258 are provided, via steps 304 and 306, respectively. The free layer 140 or 260 is provided, via step 308. If the magnetic element 250 is being fabricated, then the spacer layer 262, pinned layer 264 and any pinning layers 266 may be provided, via steps 310, 312, and 314, respectively. At least the free layer 140 or 260 has the cross-section in the S-shape 150 or 150′, via step 316. Step 316 may form the S-shape from only the free layer 140 or 260, from only the free layer 140 and 260 and layer(s) above the free layer 140 or 260, from the free layer 140 or 260 and additional layer(s) above and/or below the magnetic element 100 or 250, respectively. Moreover, the entire magnetic element 100 or 250 may be formed in the S-shape 150 or 150′ using step 316. Thus, the magnetic element 100 and 250 may be provided, and their advantages achieved.

A method and system for providing a magnetic element having improved switching characteristics and a magnetic memory using the magnetic element have been disclosed. The present invention has been described in accordance with the embodiments shown, and one of ordinary skill in the art will readily recognize that there could be variations to the embodiments, and any variations would be within the spirit and scope of the present invention. Accordingly, many modifications may be made by one of ordinary skill in the art without departing from the spirit and scope of the appended claims.

We claim:

1. A magnetic element comprising:
a pinned layer;
a spacer layer, the spacer layer being nonferromagnetic; and
a free layer, the spacer layer residing between the pinned layer and the free layer, at least the free layer having a first end portion, a second end portion and a central portion between the first end portion and the second end portion, the first end portion, the second end portion and the central portion forming an S-shape, at least one of the first end portion and the second end portion including a curve;
wherein the magnetic element is configured to allow the free layer to be switched at least in part due to spin transfer when a write current is passed through the magnetic element.

2. The magnetic element of claim 1 wherein the S-shape has a perimeter free of corners.

3. The magnetic element of claim 1 wherein the first end portion and the second end portion each has an inside curve and an outside curve, the inside curve and the outside curve forming a portion of a perimeter.

4. The magnetic element of claim 3 wherein the first end portion and the second end portion each have an end forming an end curve.

5. The magnetic element of claim 4 wherein the inside curve has a first radius.

6. The magnetic element of claim 5 wherein the end curve has a second radius.

7. The magnetic element of claim 6 wherein the outside curve has a third radius equal to the first radius plus twice the second radius.

8. The magnetic element of claim 7 wherein second radius is not greater than two hundred nanometers.

9. The magnetic element of claim 7 wherein the central portion has a first side and a second side, the first side and the second side being substantially straight and forming another portion of a perimeter of the S-shape.

10. The magnetic element of claim 3 wherein the central portion has a first side and a second side, the first side and the second side being substantially straight and forming another portion of a perimeter of the S-shape.

11. The magnetic element of claim 10 wherein the first side and the second side are substantially parallel.

12. The magnetic element of claim 11 wherein the first end and the second end are separated by a width.

13. The magnetic element of claim 1 wherein the first end portion has a first inside curve and a first outside curve and the second end portion has a second inside curve and a second outside curve, the first inside curve, the second inside curve, the first outside curve and the second outside curve forming a portion of a perimeter.

14. The magnetic element of claim 13 wherein the first inside curve has a first radius and the second inside curve has a second radius different from the first radius.

15. The magnetic element of claim 14 wherein the first outside curve has a third radius and the second outside curve has a fourth radius different from the third radius.

16. The magnetic element of claim 1 wherein the spacer layer is conductive.

17. The magnetic element of claim 1 wherein the spacer layer is insulating.

18. The magnetic element of claim 1 further comprising:
an additional spacer layer, the additional spacer layer being nonferromagnetic, the free layer residing between the additional spacer layer and the spacer layer; and
an additional pinned layer, the additional spacer layer residing between the free layer and the additional pinned layer.

19. The magnetic element of claim 18 wherein at least one of spacer layer and the additional spacer layer is insulating.

20. The magnetic element of claim 19 wherein the other of the spacer layer and the additional spacer layer is conductive.

21. The magnetic element of claim 18 wherein at least one of the spacer layer and the additional spacer layer is conductive.

22. The magnetic element of claim 1 wherein the spacer layer has a shape substantially the same as the S-shape.

23. The magnetic element of claim 1 wherein the pinned layer has a shape substantially the same as the S-shape.

24. The magnetic element of claim 1 wherein the pinned layer is a synthetic pinned layer including at least a first ferromagnetic layer, a second ferromagnetic layer, and a nonmagnetic spacer layer residing between the first ferromagnetic layer and the second ferromagnetic layer.

25. The magnetic element of claim 1 wherein the free layer is a synthetic free layer including at least a first ferromagnetic layer, a second ferromagnetic layer, and a nonmagnetic spacer layer residing between the first ferromagnetic layer and the second ferromagnetic layer.

26. The magnetic element of claim 1 further comprising:
a pinning layer for pinning a magnetization of the pinned layer in a first direction.

27. The magnetic element of claim 1 wherein the central portion has a long axis and a short axis, the S shape is asymmetric with respect to both long and short axes of the central portion.

28. The magnetic element of claim 1 wherein the central portion has a center and wherein the S-shape has a rotational or an inversion symmetry about the center.

29. A magnetic element comprising:
a first ferromagnetic layer;
a spacer layer, the spacer layer being nonferromagnetic; and
a second ferromagnetic layer, the spacer layer residing between the first ferromagnetic layer and the second ferromagnetic layer, at least one of the first ferromagnetic layer and the second ferromagnetic layer having a first end portion, a second end portion and a central portion between the first end portion and the second end portion, the first end portion, the second end portion and the central portion forming an S-shape, at least one of the first end portion and the second end portion including a curve;
wherein the magnetic element is configured to allow at least one of the first ferromagnetic layer and the second ferromagnetic layer to be switched at least in part due to spin transfer when a write current is passed through the magnetic element.

30. A magnetic element comprising:
a pinned layer;
a spacer layer, the spacer layer being nonferromagnetic; and
a free layer, the spacer layer residing between the pinned layer and the free layer, at least the free layer having an S-shape having a perimeter substantially free of corners, the S-shape further including a first end portion, a second end portion, and a central portion between the first end portion and the second end portion, the first end portion and the second end portion each having an inside curve having a first radius, an outside curve having a second radius, and an end curve having a third radius, the inside curve, the outside curve, and the end curve each forming a portion of the perimeter, the second radius being the first radius plus twice the third radius, the central portion having a first side and a second side, the first side and the second side forming another portion of the perimeter, the first side and the second side being substantially parallel and having a width equal to twice the third radius;
wherein the magnetic element is configured to allow the free layer to be switched at least in part due to spin transfer when a write current is passed through the magnetic element.

31. A magnetic memory comprising:
a plurality of magnetic elements, each of the plurality of magnetic elements including a pinned layer, a spacer layer, and a free layer, the spacer layer being nonferromagnetic and residing between the free layer and the pinned layer, at least the free layer having a first end portion, a second end portion and a central portion between the first end portion and the second end portion, the first end portion, the second end portion and the central portion forming an S-shape, at least one of the first end portion and the second end portion including a curve, the magnetic element being configured to allow the free layer to be switched at least in part due to spin transfer when a write current is passed through the magnetic element; and
a plurality of write lines for providing the write current.

32. The magnetic memory of claim 31 wherein the S-shape has a perimeter free of corners.

33. The magnetic memory of claim 31 wherein the first end portion and the second end portion each has an inside curve and an outside curve, the inside curve and the outside curve forming a portion of a perimeter.

34. The magnetic memory of claim 33 wherein the first end portion and the second end portion each have an end forming an end curve.

35. The magnetic memory of claim 34 wherein the inside curve has a first radius.

36. The magnetic memory of claim 35 wherein the end curve has a second radius.

37. The magnetic memory of claim 36 wherein the outside curve has a third radius equal to the first radius plus twice the second radius.

38. The magnetic memory of claim 37 wherein second radius is not greater than two hundred nanometers.

39. The magnetic memory of claim 37 wherein the central portion has a first side and a second side, the first side and the second side being substantially straight and forming another portion of a perimeter of the S-shape.

40. The magnetic memory of claim 33 wherein the central portion has a first side and a second side, the first side and the second side being substantially straight and forming another portion of a perimeter of the S-shape.

41. The magnetic memory of claim 40 wherein the first side and the second side are substantially parallel.

42. The magnetic memory of claim 41 wherein the first end and the second end each separated by a width.

43. The magnetic memory of claim 31 wherein the S-shape further includes a first end portion, a second end portion, and a central portion between the first end portion and the second end portion, the first end portion having a first inside curve and a first outside curve and the second end portion each having a second inside curve and a second outside curve, the first inside curve, the second inside curve, the first outside curve and the second outside curve forming a portion of a perimeter.

44. The magnetic memory of claim 43 wherein the first inside curve has a first radius and the second inside curve has a second radius different from the first radius.

45. The magnetic memory of claim 44 wherein the first outside curve has a third radius and the second outside curve has a fourth radius different from the third radius.

46. The magnetic memory of claim 31 wherein the spacer layer is conductive.

47. The magnetic memory of claim 31 wherein the spacer layer is insulating.

48. The magnetic memory of claim 31 wherein each of the plurality of magnetic elements further includes:
an additional spacer layer, the additional spacer layer being nonferromagnetic, the free layer residing between the additional spacer layer and the spacer layer; and
an additional pinned layer, the additional spacer layer residing between the free layer and the additional pinned layer.

49. The magnetic memory of claim 48 wherein at least one of spacer layer and the additional spacer layer is insulating.

50. The magnetic memory of claim 49 wherein the other of the spacer layer and the additional spacer layer is conductive.

51. The magnetic memory of claim 48 wherein at least one of the spacer layer and the additional spacer layer is conductive.

52. The magnetic memory of claim 31 wherein the spacer layer has a shape substantially the same as the S-shape.

53. The magnetic memory of claim 31 wherein the pinned layer has a shape substantially the same as the S-shape.

54. The magnetic memory of claim 31 wherein the pinned layer is a synthetic pinned layer including at least a first ferromagnetic layer, a second ferromagnetic layer, and a nonmagnetic spacer layer residing between the first ferromagnetic layer and the second ferromagnetic layer.

55. The magnetic memory of claim 31 wherein the free layer is a synthetic free layer including at least a first ferromagnetic layer, a second ferromagnetic layer, and a nonmagnetic spacer layer residing between the first ferromagnetic layer and the second ferromagnetic layer.

56. The magnetic memory of claim 31 wherein each of the plurality of magnetic elements further includes:
a pinning layer for pinning a magnetization of the pinned layer in a first direction.

57. The magnetic memory of claim 31 wherein the central portion has a long axis and a short axis, the S shape is asymmetric with respect to both long and short axes of the central portion.

58. The magnetic memory of claim 31 wherein the central portion has a center and wherein the S-shape has a rotational or an inversion symmetry about the center.

59. A magnetic memory comprising:
a plurality of magnetic elements, each of the plurality of magnetic elements including a pinned layer, a spacer layer and a free layer, the spacer layer being nonferromagnetic and residing between the free layer and the pinned layer, at least the free layer having an S-shape having a perimeter substantially free of corners, the S-shape further including a first end portion, a second end portion, and a central portion between the first end portion and the second end portion, the first end portion and the second end portion each having an inside curve having a first radius, an outside curve having a second radius, and an end curve having a third radius, the inside curve, the outside curve, and the end curve each forming a portion of the perimeter, the second radius being the first radius plus twice the third radius, the central portion having a first side and a second side, the first side and the second side forming another portion of the perimeter, the first side and the second side being substantially parallel and having a width equal to twice the third radius, the magnetic element being configured to allow the free layer to be switched at least in part due to spin transfer when a write current is passed through the magnetic element; and
a plurality of write lines for providing the write current.

60. A method for providing a magnetic memory comprising:
providing a pinned layer;
providing a spacer layer, the spacer layer being nonferromagnetic; and
providing a free layer, the spacer layer residing between the pinned layer and the free layer, at least the free layer having a first end portion, a second end portion and a central portion between the first end portion and the second end portion, the first end portion, the second end portion and the central portion forming an S-shape, at least one of the first end portion and the second end portion including a curve;
wherein the magnetic element is configured to allow the free layer to be switched at least in part due to spin transfer when a write current is passed through the magnetic element.
